(19) United States
(12) Patent Application Publication
(10) Pub. No.: US 2026/0358383 A1
(43) Pub. Date: Nov. 12, 2026

(54) SEMICONDUCTOR DEVICE FOR DETECTING VOLTAGE

(71) Applicant: Renesas Electronics Corporation, Tokyo (JP)

(72) Inventor: Zhiqiang LI, Beijing (CN)

(21) Appl. No.: 19/668,975

(22) Filed: May 6, 2026

(30) Foreign Application Priority Data
May 8, 2025 (CN) 202510595558.7

(51) Int. Cl. G01R 19/165

(52) U.S. Cl. CPC G01R 19/16576

(57) ABSTRACT

A semiconductor device for detecting voltage includes: one voltage detection circuit configured to compare a voltage to be detected with a voltage threshold indicated by a first signal to generate a comparison result; a logic controller configured to determine the first signal based on a second signal from a system register and a third signal from a system memory, the second signal including at least a first voltage threshold for interrupt voltage detection, the third signal including at least a second voltage threshold for reset voltage detection; a control signal generator configured to generate a reset request signal or an interrupt request signal based on the comparison result and a selection information. The selection information indicates whether the control signal generator generates a reset request signal or an interrupt request signal. The second signal is changeable during operation of the semiconductor device.

### TECHNICAL FIELD

The present disclosure relates to the field of electronics, and more specifically to a semiconductor device, a detection method, a medium, and a program product for detecting voltage.

### BACKGROUND

A disclosed technology is listed below.
[Patent document 1] Japanese Laid-Open Patent Application Publication JP2012003692A.

A system for voltage detection has been developed. For example, Patent document 1 discloses a voltage detection system having an interrupt detection mode and a reset detection mode.

### SUMMARY

The system for voltage detection in Patent document 1 uses a first detection level and a second detection level, and generates an interrupt signal when the power supply voltage is lower than the first detection level, and generates a reset signal when the power supply voltage becomes lower than the second detection level. Patent document 1 does not disclose the use of a single voltage detection circuit to implement a functional combination of the option bytes and special function register SFR to achieve two or more levels of low voltage detection. Other purposes and novel features will become apparent from the description of this specification and the accompanying drawings.

According to a first aspect of the present disclosure, a semiconductor device comprises: one voltage detection circuit, the voltage detection circuit is configured to compare the voltage to be detected with a voltage threshold indicated by a first signal to generate a comparison result; a logic controller, the logic controller is configured to determine a first signal based on a second signal from a system register and a third signal from a system memory, the second signal comprising at least a first voltage threshold for interrupt voltage detection, and the third signal comprising at least a second voltage threshold for reset voltage detection; a control signal generator, the control signal generator is configured to generate a reset request signal or an interrupt request signal based on the comparison result and a selection information, wherein the selection information indicates whether the control signal generator generates a reset request signal or an interrupt request signal, wherein the second signal is changeable during an operation of the semiconductor device.

By adopting the semiconductor device of the present disclosure, the following technical effects can be achieved. First, the semiconductor device of the present disclosure comprises only one voltage detection circuit, so it has advantages in occupying less device area and reducing costs. In addition, smooth switching of reset voltage detection and interrupt voltage detection is achieved through the logic controller and the selection information. In addition, the register signal is changeable multiple times, so it has advantages in flexibly setting voltage detection parameters.

According to the second aspect of the present disclosure, a method for detecting voltage comprises: performing voltage detection with the semiconductor device of the first aspect, wherein after the electronic system is powered on, the memory of the electronic system transmits the third signal to the logic controller, and upon powering on the electronic system for a first period, the register of the electronic system transmits the second signal to the logic controller.

According to the third aspect of the present disclosure, a computer program product is provided. The computer program comprises computer executable instructions. When the computer executable instructions are executed by a processor, the method according to the first aspect is implemented.

According to the fourth aspect of the present disclosure, a computer readable storage medium is provided, on which a computer program is stored. When the computer program is executed by a processor, the method according to the first aspect is implemented.

It should be understood that the content described in the invention content section is not intended to limit the key or important features of the embodiments of the present disclosure, nor is it intended to limit the scope of the present disclosure. Other features of the present disclosure will become easier to understand through the following description.

### BRIEF DESCRIPTION OF THE DRAWINGS

The above and other features, advantages and aspects of the embodiments of the present disclosure will become more apparent in conjunction with the accompanying drawings and with reference to the following detailed description. In the accompanying drawings, the same or similar reference numerals represent the same or similar elements, wherein:

FIG. 1A shows a low voltage detection structure of an electronic product in some related technologies;

FIG. 1B shows a detection timing diagram of the low voltage detection structure shown in FIG. 1A;

FIG. 2A shows a low voltage detection structure of an electronic product in some other related technologies;

FIG. 2B shows a detection timing diagram of the low voltage detection structure shown in FIG. 2A;

FIG. 3A shows a schematic diagram of a semiconductor device for detecting low voltage according to the present disclosure;

FIG. 3B is a specific schematic diagram of a semiconductor device for detecting low voltage according to an embodiment of the present disclosure;

FIG. 4 shows a detailed schematic diagram of an embodiment of a semiconductor device for detecting low voltage according to the present disclosure;

FIG. 5 shows a method for low voltage detection with the semiconductor device shown in FIG. 4;

FIG. 6 shows a timing diagram of low voltage detection of the semiconductor device shown in FIG. 4;

FIG. 7 shows a detailed schematic diagram of another embodiment of a semiconductor device for detecting low voltage according to the present disclosure;

FIG. 8 shows a block diagram of a device capable of implementing multiple embodiments of the present disclosure.

### DETAILED DESCRIPTION

The embodiments of the present disclosure will be described in more detail with reference to the accompanying drawings. Although certain embodiments of the present disclosure are shown in the drawings, it should be understood that the present disclosure can be implemented in various forms and should not be construed as being limited to the embodiments described herein. Instead, these embodiments are provided to provide a more thorough and complete understanding of the present disclosure. It should be understood that the drawings and embodiments of the present disclosure are only for exemplary purposes and are not intended to limit the scope of protection of the present disclosure.

In the description of the embodiments of the present disclosure, the term “including” and similar terms should be understood as open inclusion, i.e., “including but not limited to”. The term “based on” should be understood as “based at least in part on”. The term “one embodiment” or “the embodiment” should be understood as “at least one embodiment”. The terms “first”, “second”, etc. may refer to different or the same objects. Other explicit and implicit definitions may also be included below.

The preferred embodiments of the present disclosure will be described in more detail below with reference to the drawings. Although the preferred embodiments of the present disclosure are shown in the drawings, it should be understood that the present disclosure can be implemented in various forms and should not be limited by the embodiments described herein. Instead, these embodiments are provided to make the present disclosure more thorough and complete, and to fully convey the scope of the present disclosure to those skilled in the art.

Low Voltage Detection (LVD) is a key function in electronic product design. It is mainly utilized to detect the power supply voltage and take corresponding measures when the voltage is lower than the set threshold. Low voltage detection is indispensable in electronic products because electronic devices usually need to work within a specific voltage range. Low voltage may cause system instability, data loss or malfunction. LVD can detect voltage drop in time to prevent the system from operating in an abnormal working state. In addition, low voltage may damage electronic components (such as processors, memory, etc.). LVD can shut down the system or enter protection mode when the voltage is insufficient to avoid hardware damage. For battery-powered devices (such as mobile phones, laptops, IoT devices, etc.), the battery voltage will gradually decrease with use. LVD can detect low battery power and remind users to charge or automatically enter low power mode.

In electronic product design, how to use fewer electronic components to achieve the function of low voltage detection has become a technical problem that should be addressed.

### Comparative Examples

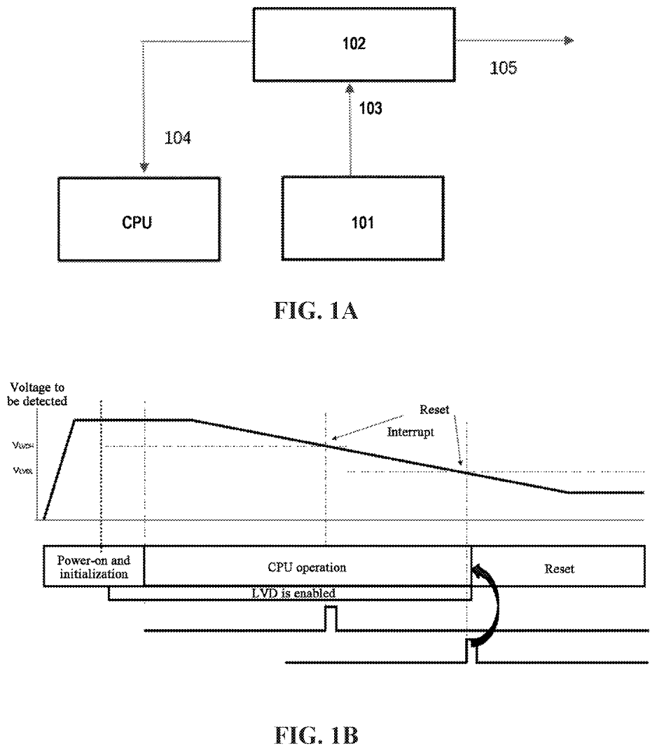

As shown in FIG. 1A, in the low voltage detection of electronic products in some related technologies, a signal 103 pre-set on the system memory 101 is utilized as an input signal of the voltage detection circuit 102 to indicate the voltage threshold, etc. After the system is powered on, the preset value on the system memory 101 is transmitted to the voltage detection circuit 102. The voltage detection circuit 102 performs low voltage detection according to the voltage threshold indicated by the signal 103. This operation is completed before the system CPU is started, so the low voltage detection can be performed before the CPU is started to ensure that the system is supplied with the necessary voltage. The voltage detection circuit 102 can generate an interrupt request signal 104 or a reset request signal 105 according to the detection result for subsequent processing.

FIG. 1B shows a detection timing diagram of the low voltage detection structure shown in FIG. 1A. As shown in FIG. 1B, when the system power is powered on, the information in the system memory 101 is loaded, and the low voltage detection (LVD) becomes enabled. At this time, the selection of the interrupt voltage threshold (V_{LVDH}) and the reset voltage threshold (V_{LVDL}) is also determined. Later, the CPU starts working. As can be seen from the figure, LVD becomes enabled before the CPU works. As time goes by, when the detected voltage drops below the interrupt voltage threshold V_{LVDH}, the interrupt request signal is triggered, and the voltage detection threshold is switched to the reset voltage threshold V_{LVDL}. After another period of time, when the detected voltage drops below the voltage threshold V_{LVDL}, a reset request signal is triggered. In this process, because the signal is a signal from the system memory 101, the voltage thresholds V_{LVDH} and V_{LVDL} are not changeable during the operation of the system.

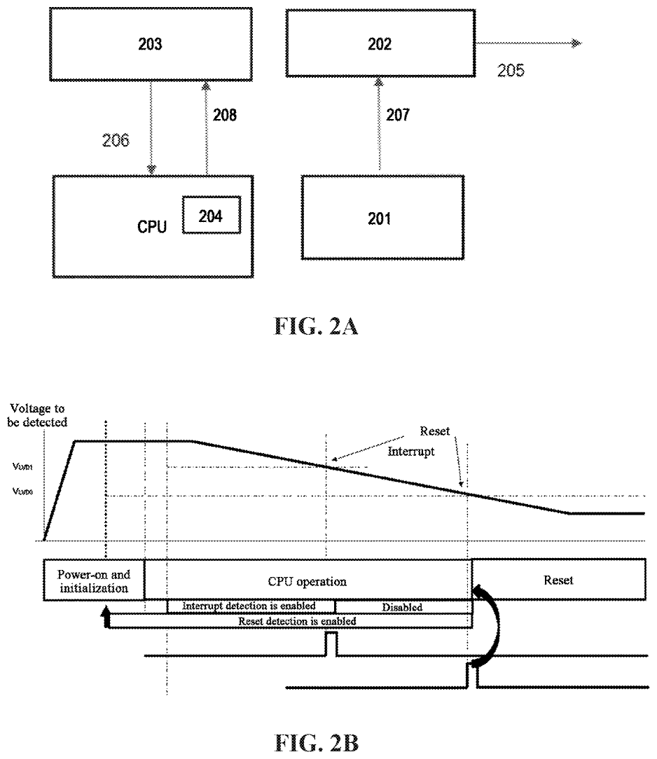

As shown in FIG. 2A, in the low voltage detection of electronic products of other related technologies, two voltage detection circuits 202 and 203 are utilized. The reset voltage detection circuit 202 uses a signal 207 pre-set on the system memory 201 as an input signal indicating the reset voltage threshold, and generates a reset request signal 205 when the reset voltage detection circuit 202 detects a low voltage. On the other hand, the interrupt voltage detection circuit 203 uses a signal 208 from the system register 204 as an input signal indicating the interrupt voltage threshold. When the interrupt voltage detection circuit 203 detects a low voltage below the interrupt voltage threshold, an interrupt request signal 206 is generated. In this low voltage detection, a control signal is required to control the enable and disable status of the two voltage detection circuits 202 and 203.

FIG. 2B shows a detection timing diagram of the low voltage detection structure shown in FIG. 2A. As shown in FIG. 2B, when the system is powered on, the information in the system memory 201 is loaded, the reset detection becomes enabled, and the reset voltage threshold V_{LVD0} is also determined. Later, the CPU starts working, the signal of the system register 204 can be provided to the interrupt voltage detection circuit, the interrupt detection becomes enabled, and the interrupt voltage threshold V_{LVD1} is indicated, wherein V_{LVD1}>V_{LVD0}. As can be seen from the figure, when the detected voltage drops below the interrupt voltage threshold V_{LVD1}, the interrupt request signal is triggered, and thereafter the interrupt detection is set to be disabled, and the reset detection becomes enabled. After another period of time, when the detected voltage drops below the reset voltage threshold V_{LVD0}, the reset request signal is triggered.

In the structure shown in FIG. 2A, since the data of the system register 204 is changeable by software, the interrupt voltage threshold V_{LVD1} is changeable during the system operation after the CPU is started. The two voltage detection circuits 202 and 203 can work independently, and the advantage of flexibly setting or changing the interrupt voltage threshold can be obtained through the signal from the register 204. However, in the structure shown in FIG. 2A, there are two voltage detection circuits. As a result, the hardware occupies more space, and the hardware cost is higher.

### Exemplary Embodiments of the Present Disclosure

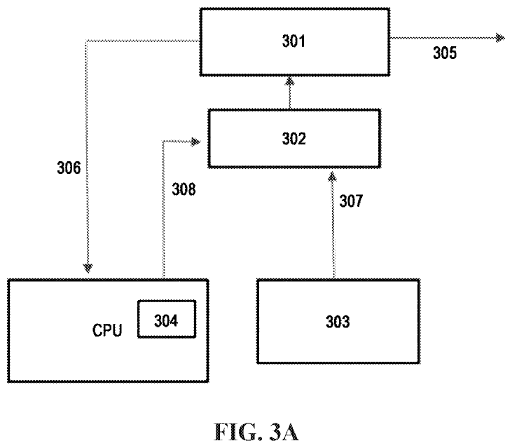

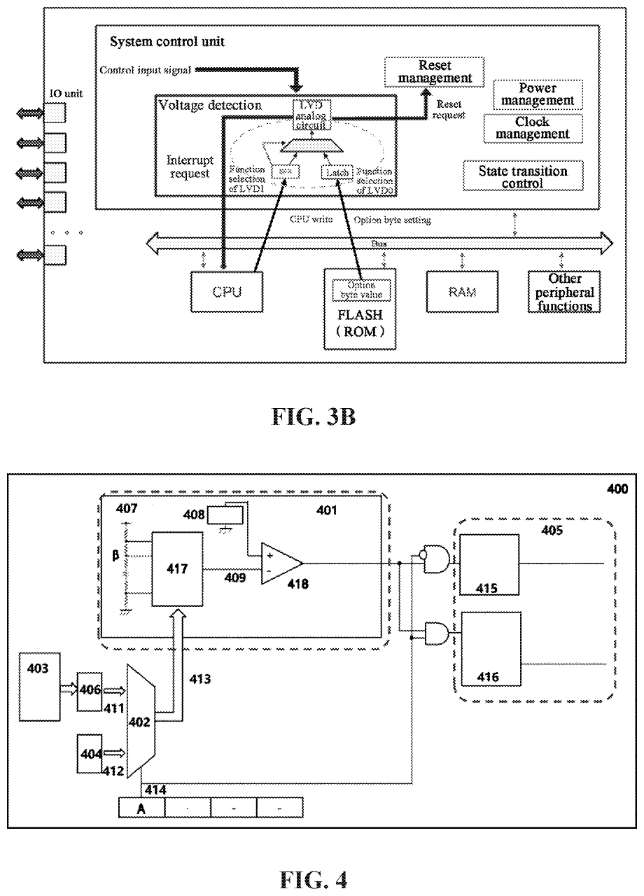

FIG. 3A shows a schematic diagram of a semiconductor device for detecting low voltage according to the present disclosure. As shown in FIG. 3A, one voltage detection circuit 301 is included in the semiconductor device of the present disclosure. A signal 307 from a system memory 303 and a signal 308 from a system register 304 are input to a logic controller 302. The output of the logic controller 302 based on the signals 307 and 308 is transmitted to the voltage detection circuit 301, indicating the current voltage threshold of the voltage detection circuit 301 and the signal to be generated when the detected voltage is lower than the voltage threshold. When the voltage detection circuit 301 detects a low voltage lower than the reset voltage threshold, a reset request signal 305 is generated. On the other hand, when the voltage detection circuit 301 detects a low voltage lower than the interrupt voltage threshold, an interrupt request signal 306 is generated. Compared with the structure of FIG. 2A, the structure shown in FIG. 3 can obtain the advantage of flexibly setting or changing the interrupt voltage threshold with only one voltage detection circuit, and can also ensure that the reset voltage detection is entered after power-on. The structure shown in FIG. 3A will be described in more detail below.

FIG. 3B is a specific schematic diagram of a semiconductor device for detecting low voltage according to an embodiment of the present disclosure. As shown in FIG. 3B, the semiconductor device includes components such as a CPU, FLASH (ROM), RAM, an input and output device (IO unit), and a system control unit. The system control unit includes modules such as voltage detection, reset management, power management, clock management, and state transition control. The CPU accesses each component through the bus and sets the system control unit. Through the CPU write, the signal from the special function register SFR including information such as the voltage threshold enters the logic controller. The function selection of LVD1 (such as interrupt detection) and LVD0 (such as reset detection) is realized based on the selection information. In addition, the information of the option byte from the memory FLASH (or ROM) is provided to the logic controller through a latch. The logic controller generates a signal provided to the LVD analog circuit (voltage detection circuit) based on these signals. When the voltage detection circuit detects that the detected voltage is lower than the reset voltage threshold, a reset request signal is generated. On the other hand, when the voltage detection circuit detects that the detected voltage is lower than the interrupt voltage threshold, an interrupt request signal is generated.

FIG. 4 shows a detailed schematic diagram of a specific embodiment of a semiconductor device 400 for detecting voltage according to the present disclosure. The semiconductor device 400 includes one voltage detection circuit 401, a logic controller 402, and a control signal generator 405. The control signal generator 405 includes a first generator 415 configured to generate a reset signal and a second generator 416 configured to generate an interrupt signal.

In one embodiment, the signal 411 enters the logic controller 402 after passing through the latch 406. The signal 411 may be information from an option byte of the memory 403, and the signal includes at least the reset voltage threshold Th1. The signal 412 comes from the system register 404. The system register 404 may be a special function register SFR. The signal 412 includes at least the interrupt voltage threshold Th2. In one example, the interrupt voltage threshold Th2>the reset voltage threshold Th1. Alternatively, signal 412 may also include another reset voltage threshold Th1′, wherein Th1′>Th1.

Logic controller 402 generates signal 413 based on signals 411 and 412. In one embodiment, when both signals 411 and 412 are valid, logic controller 402 generates signal 413 based on signal 412, and when only signal 411 is valid, logic controller 402 generates signal 413 based on signal 411. In another embodiment, logic controller 402 may select to generate signal 413 using signal 412 or to generate signal 413 using signal 411 based on the value of selection signal 414.

Signal 413 includes at least a voltage threshold information Th. When only the signal 411 is valid, the logic controller 402 generates the voltage threshold information in the signal 413 based on the voltage threshold in the signal 411. For example, when the current voltage threshold in the signal 412 is Th2, the logic controller 402 generates the voltage threshold Th in the signal 413 as Th2. When only the signal 411 is valid and the current voltage threshold in the signal 411 is Th1, logic controller 402 generates the voltage threshold Th in the signal 413 as Th1. In another embodiment, similarly, when the signal 411 is selected as a valid input of the logic controller 402 based on the selection signal 414, the logic controller 402 uses the threshold Th1 as the threshold Th of the signal 413. And when the signal 412 is selected as a valid input of the logic controller 402 based on the selection signal 414, the logic controller 402 uses the threshold Th2 as the threshold Th of the signal 413.

The signal 414 from the system or system register includes at least a selection information, which indicates whether the control signal generator 405 generates a reset request signal or an interrupt request signal. For example, in a specific embodiment, as shown in FIG. 4, the selection information in the signal 414 may be the enable information A of the second generator 416. The enable bit A in the signal 414 may be utilized as the selection information. When the enable bit A is ‘0’, the data received at the end of the AND gate connected to the first generator 415 in the signal generator 405 is the result of the NOT operation of ‘0’, i.e. ‘1’, so the output of the AND gate is related to the input at the other end. That is, if the input at the other end is ‘0’, the output of the AND gate is 0, and if the input at the other end is ‘1’, the output of the AND gate is ‘1’. Correspondingly, the data received at the end of the AND gate connected to the second generator 416 in the signal generator 405 is ‘0’, so the output of the AND gate is independent of the input at the other end. That is, the output of the AND gate connected to the second generator 416 is always 0. In this case, the second generator 416 is actually disabled. At this time, only the first generator 415 is enabled.

On the other hand, when the enable bit A in the signal 414 is ‘1’, the data received at the end of the AND gate connected to the first generator 415 in the signal generator 405 is the result of the NOT operation of ‘1’, i.e. ‘0’, so the output of the AND gate is independent of the input at the other end. That is, the output of the AND gate connected to the first generator 415 is always 0. In this case, the first generator 415 is actually disabled. Correspondingly, the data received at the end of the AND gate connected to the second generator 416 in the signal generator 405 is ‘1’, so the output of the AND gate is related to the input at the other end. That is, if the input at the other end is ‘0’, the output of the AND gate is 0, and if the input at the other end is ‘1’, the output of the AND gate is ‘1’. In this case, the first generator 415 is disabled, and only the second generator 416 is enabled.

The voltage detection circuit 401 receives the voltage to be detected 407 and the signal 413 as inputs. In one embodiment, the voltage to be detected 407 may be a system power supply voltage. It can be understood that the voltage to be detected 407 can also be other voltages. The voltage detection circuit 401 compares the voltage to be detected 407 with the voltage threshold Th indicated in the signal 413. For example, when the detected voltage 407 is greater than or equal to the voltage threshold Th, the voltage detection circuit 401 outputs a comparison result of 0. When the detected voltage 407 is less than the voltage threshold Th, the voltage detection circuit 401 outputs a comparison result of 1.

In the specific embodiment of FIG. 4, the voltage detection circuit 401 includes a proportional circuit 417 and a comparator 418. Assume that the ratio of the proportional circuit 417 is β. The ratio β is indicated, for example, by a signal 413 from the logic controller 402. β varies according to the reference voltage 408 and the voltage threshold Th, so that β=reference voltage 408/voltage threshold Th. Under the action of this proportional circuit 417, the internal comparison voltage 409=the voltage to be detected 407*β. By conversion, it can be seen that, in fact, the ratio of the internal comparison voltage 409 to the reference voltage 408 is equal to the ratio of the voltage to be detected 407 to the voltage threshold Th. The comparator 418 compares the reference voltage 408 with the internal comparison voltage 409, and the comparison result of the comparator 418 is utilized as the comparison result of the voltage detection circuit 401. In this specific embodiment, the comparison between the detected voltage 407 and the voltage threshold Th can be realized with a simple proportional circuit 417 and a comparator 418. Of course, the voltage detection circuit 401 can have any structure as long as it can compare the voltage to be detected 407 with the voltage threshold Th.

Through the above structure, in a structure with only a single voltage detection circuit 401, a logic controller 402 that receives signals from both the system memory and the system register is provided. On one hand, the number of voltage detection circuits is reduced, and on the other hand, the voltage threshold can be easily changed during system operation using the signal of the system register. In addition, the selection information, such as the enable bit A, is flexibly utilized, so that although only a single voltage detection circuit 401 is utilized, it seems to the user that there are two voltage detection circuits.

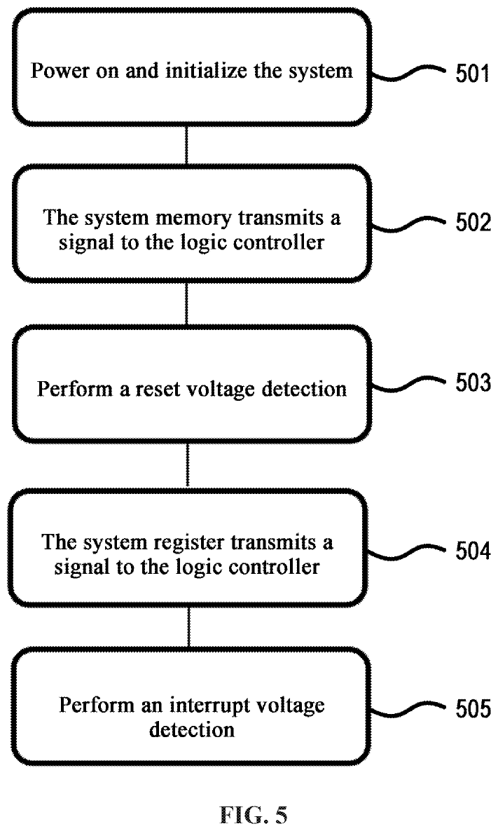

Below, the method 500 for low voltage detection with the semiconductor device shown in FIG. 4 is described in conjunction with FIG. 5. At 501, the system is powered on and initialized. In 502, the system memory transmits a signal to the logic controller, which includes at least a reset voltage threshold. The signal can also be transmitted to the logic controller through a latch. In this case, the voltage threshold in the signal 413 of the semiconductor device is the reset voltage threshold. The selected information in the signal 414 indicates that a reset request signal should be generated. In 503, the reset voltage detection is performed by the voltage detection circuit.

In 504, after the system is powered on for a first period of time, the system register transmits a signal to the logic controller, which includes at least an interrupt voltage threshold. The voltage threshold in the signal 413 of the semiconductor device becomes an interrupt voltage threshold. The selection information in the signal 414 indicates that an interrupt request signal should be generated. In 505, the interrupt voltage detection is performed by the voltage detection circuit.

Optionally, when the detected voltage is lower than the interrupt voltage threshold, after the control signal generator generates an interrupt request signal, the system register transmits a changed signal to the logic controller, wherein the changed signal includes the changed interrupt voltage threshold. Of course, since the data of the system register is changeable multiple times, the change of the signal can be repeated multiple times.

Further optionally, when the detected voltage is lower than the changed interrupt voltage threshold, after the control signal generator generates another interrupt request signal, the system register stops transmitting signals to the logic controller. At this time, only the signal of the system memory is input to the logic controller, and the voltage threshold in the signal 413 of the semiconductor device becomes the reset voltage threshold. The semiconductor device changes to reset voltage detection.

FIG. 6 shows a timing diagram of low voltage detection of the semiconductor device shown in FIG. 4. After power-on and initialization, the system memory transmits a signal to the logic controller, the signal includes at least the reset voltage threshold, and the reset voltage detection becomes enabled. Later, the CPU starts and causes the system register to transmit a signal to the logic controller, the signal includes at least the interrupt voltage threshold. In this case, the interrupt voltage detection becomes enabled, and the reset voltage detection becomes disabled. When the detected voltage is lower than the interrupt voltage threshold V_{LVD1}, the system register can change the interrupt voltage threshold in the signal to a new interrupt voltage threshold, as shown by the new threshold V_{LVD1 (new)} between V_{LVD1} and V_{LVD0} in FIG. 6. When the detected voltage is lower than the changed interrupt voltage threshold V_{LVD1 (new)} and the control signal generator generates another interrupt request signal, at this time, the system register stops transmitting signals to the logic controller, the interrupt voltage detection becomes disabled, and the reset voltage detection becomes enabled. When the detected voltage is lower than the reset voltage threshold V_{LVD0}, a reset request signal is generated.

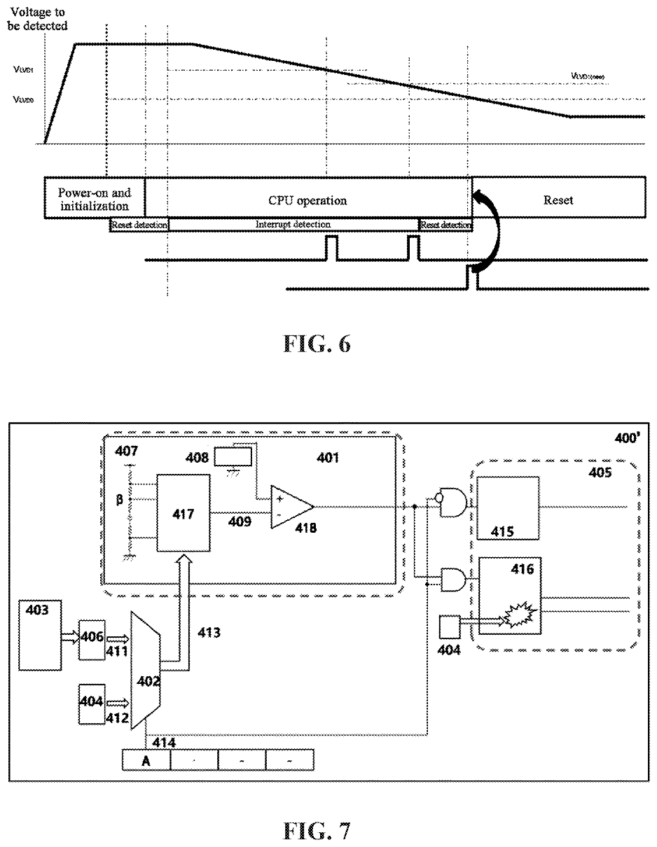

FIG. 7 shows a detailed schematic diagram of a semiconductor device 400′ for detecting low voltage according to another embodiment of the present disclosure. Here, only the parts that are different from FIG. 4 are described, and the parts similar to FIG. 4 are not repeated. As shown in FIG. 7, in the control signal generator 405, the second generator 416 may also generate a reset request signal. In this case, a reset voltage threshold is also included in the signal 412 from the system register. In addition, the signal 412 of the system register 404 can also include an information notifying the second generator 416 that a reset request signal can be generated, the information is utilized in combination with other inputs of the second generator 416, so that when the signal 412 includes a reset voltage threshold and the detected voltage is lower than the reset voltage threshold, the second generator 416 generates a reset request signal.

By adopting the semiconductor device for detecting low voltage disclosed in the present invention, the following technical effects can be achieved. First, the semiconductor device disclosed in the present invention includes only one voltage detection circuit, so it has advantages in occupying less device area and reducing costs. In addition, the smooth switching of reset voltage detection and interrupt voltage detection is achieved through the logic controller and a selection information (such as an enable bit). In addition, the register signal is changeable multiple times, so it has advantages in flexibly setting voltage detection parameters.

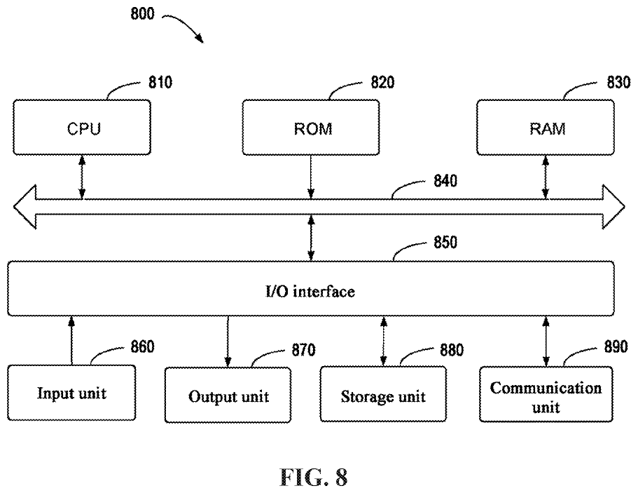

FIG. 8 shows a block diagram of a device that can implement multiple embodiments of the present invention. The device 800 includes a computing unit 810, which can perform various appropriate actions and processes according to computer program instructions stored in a random access memory (RAM) 830 and/or a read-only memory (ROM) 820 or computer program instructions loaded from a storage unit 880 into the RAM 830 and/or the ROM 820. In the RAM 830 and/or the ROM 820, various programs and data required for the operation of the device 800 can also be stored. The computing unit 810 and the RAM 830 and/or the ROM 820 are connected to each other via a bus 840. An input/output (I/O) interface 850 is also connected to the bus 840.

Multiple components in the device 800 are connected to the I/O interface 850, including: an input unit 860, such as a keyboard, a mouse, etc.; an output unit 870, such as various types of displays, speakers, etc.; a storage unit 880, such as a disk, an optical disk, etc.; and a communication unit 890, such as a network card, a modem, a wireless communication transceiver, etc. The communication unit 890 allows the device 800 to exchange information/data with other devices through a computer network such as the Internet and/or various telecommunication networks.

The computing unit 810 can be various general and/or special processing components with processing and computing capabilities. Some examples of the computing unit 810 include, but are not limited to, a central processing unit (CPU), a graphics processing unit (GPU), various special artificial intelligence (AI) computing chips, various computing units running machine learning model algorithms, a digital signal processor (DSP), and any appropriate processor, controller, microcontroller, etc. The computing unit 810 performs the various methods and processes described above, such as method 500. In some embodiments, part or all of the computer program may be loaded and/or installed on the device 800 via the RAM and/or ROM and/or the communication unit 890. When the computer program is loaded into the RAM and/or ROM and executed by the computing unit 810, one or more steps of the method 500 described above may be executed. Alternatively, in other embodiments, the computing unit 810 may be configured to execute the method 500 in any other appropriate manner (e.g., by means of firmware).

In the above embodiments, the method flow may be implemented in whole or in part by software, hardware, firmware, or any combination thereof. When implemented by software, it may be implemented in whole or in part in the form of a computer program product. The computer program product includes one or more computer instructions. When the computer program instructions are loaded and executed on a server or terminal, the process or function described in the embodiment of the present disclosure is generated in whole or in part. The computer instructions may be stored in a computer-readable storage medium, or transmitted from one computer-readable storage medium to another computer-readable storage medium. For example, the computer instructions may be transmitted from one website, computer, server or data center to another website, computer, server or data center by wired (e.g., coaxial cable, optical fiber, digital subscriber line) or wireless (e.g., infrared, wireless, microwave, etc.) means. The computer-readable storage medium may be any available medium accessible to a server or terminal or a data storage device such as a server or data center that includes one or more available media integrated therein. The available medium may be a magnetic medium (e.g., a floppy disk, a hard disk, a magnetic tape, etc.), an optical medium (e.g., a digital video disk (DVD), etc.), or a semiconductor medium (e.g., a solid-state hard disk, etc.).

The above has described various embodiments of the present disclosure, and the above description is exemplary, not exhaustive, and is not limited to the disclosed embodiments. Without departing from the scope and spirit of the described embodiments, many modifications and changes are obvious to those of ordinary skill in the art. The terminology utilized in this article is selected to best explain the principles of each embodiment, practical application or improvement of technology in the market, or to enable other ordinary technicians in this technical field to understand the embodiments disclosed in this article.

Although the subject matter has been described in language specific to structural features and/or method logical actions, it should be understood that the subject matter defined in the attached claims is not necessarily limited to the specific features or actions described above. On the contrary, the specific features and actions described above are merely example forms of implementing the claims.

1. A semiconductor device, comprising:
one voltage detection circuit configured to compare a voltage to be detected with a voltage threshold indicated by a first signal to generate a comparison result,
a logic controller configured to determine the first signal based on a second signal from a system register and a third signal from a system memory, the second signal comprising at least a first voltage threshold for interrupt voltage detection, the third signal comprising at least a second voltage threshold for reset voltage detection,
a control signal generator configured to generate a reset request signal or an interrupt request signal based on the comparison result and a selection information,
wherein the selection information indicates whether the control signal generator generates a reset request signal or an interrupt request signal,
wherein the second signal is changeable during an operation of the semiconductor device.

2. The semiconductor device according to claim 1, wherein the logic controller is configured to:
generate the first signal based on the second signal when both the second signal and the third signal are valid, or
generate the first signal based on the third signal when only the third signal is valid.

3. The semiconductor device according to claim 2, wherein the control signal generator comprises a first generator that generates a reset request signal and a second generator that generates an interrupt request signal.

4. The semiconductor device according to claim 3, wherein the second generator is configured to generate a reset request signal, and the second signal comprises a third voltage threshold for reset voltage detection.

5. The semiconductor device according to claim 1, wherein the change of the second signal comprises a change of the first voltage threshold.

6. The semiconductor device according to claim 1, wherein the system register is a special function register, the system memory is a ROM or a FLASH memory, and the third signal is a signal from an option byte of the system memory.

7. The semiconductor device according to claim 1, wherein the voltage detection circuit is configured to:
generate an internal comparison voltage with the detected voltage and the voltage threshold; and
generate the comparison result by comparing the internal comparison voltage with a reference voltage, wherein the ratio of the internal comparison voltage to the reference voltage is equal to the ratio of the detected voltage to the voltage threshold.

8. The semiconductor device according to claim 1, wherein the detected voltage is a power supply voltage.

9. A semiconductor device according to claim 1, wherein the third signal is transmitted to the logic controller through a latch.

10. A method for detecting a voltage, comprising:
performing voltage detection with a semiconductor device according to claim 1, wherein after an electronic system is powered on, a memory of the electronic system transmits the third signal to the logic controller, and
upon powering on the electronic system for a first period, a register of the electronic system transmits the second signal to the logic controller.

11. The method according to claim 10, wherein when the detected voltage is lower than the first voltage threshold indicated by the second signal, the system register transmits a changed second signal to the logic controller.

12. The method according to claim 10, wherein when the detected voltage is lower than the first voltage threshold indicated by the second signal, the system register stops transmitting the second signal to the logic controller.

13. A computer program product comprising computer executable instructions, wherein when the computer executable instructions are executed by a processor, the method according to claim 10 is implemented.

14. A computer-readable storage medium having a computer program stored thereon, wherein the computer program, when executed by a processor, implements the method according to claim 10.
